(19) United States
(12) Patent Application Publication
(10) Pub. No.: US 2011/0263111 A1
(43) Pub. Date: Oct. 27, 2011

(54) GROUP III-NITRIDE N-TYPE DOPING

(76) Inventors: Yuriy Melnik, Santa Clara, CA (US); Olga Kryliouk, Sunnyvale, CA (US); Lu Chen, Sunnyvale, CA (US); Hidehiro Kojiri, Sunnyvale, CA (US); Tetsuya Ishikawa, Saratoga, CA (US)

(21) Appl. No.: 13/071,215

(22) Filed: Mar. 24, 2011

Related U.S. Application Data
(60) Provisional application No. 61/326,560, filed on Apr. 21, 2010.

(51) Int. Cl. H01L 21/22; C30B 35/00; C23C 16/44; C23C 16/34; C23C 16/455

(52) U.S. Cl. 438/569; 118/715; 257/E21.135

(57) ABSTRACT

Group III-nitride N-type doping techniques are described.

### CROSS-REFERENCE TO RELATED APPLICATIONS

This application claims the benefit of U.S. Provisional Application No. 61/326,560, filed Apr. 21, 2010, the entire contents of which are hereby incorporated by reference herein.

### BACKGROUND

1) Field

Embodiments of the present invention pertain to the field of light-emitting diode fabrication and, in particular, to N-type doping of group III-nitride films.

2) Description of Related Art

Group III-V materials are playing an ever increasing role in the semiconductor and related, e.g. light-emitting diode (LED) or power device, industries. Often, group III-V materials are difficult to dope with charge-carrier impurity atoms to a level suitable for optimization of the electrical properties of such materials.

Furthermore, group III-V materials are often sensitive to ambient conditions and care must usually be taken to avoid such conditions at particular periods of the fabrication process. Avoiding interaction of a sensitive group III-V film with potential damaging conditions, such as doping conditions, is also not straightforward in many applications.

### BRIEF DESCRIPTION OF THE DRAWINGS

FIG. 1 is a Flowchart representing operations in a method of fabricating an N-type doped group III-V material, in accordance with an embodiment of the present invention.

FIG. 2 is a plot representing carrier concentration in n-type GaN (atoms/cm³) as a function of nitrogen (N₂) flow, in accordance with an embodiment of the present invention.

FIG. 3 includes representative optical microscope (OM) and scanning electron microscope (SEM) images of GaN film grown on PSS at different added chlorine flow rates, in accordance with an embodiment of the present invention.

FIG. 4 illustrates a screen shot of representative Hall measurements of thick n-type GaN films, in accordance with an embodiment of the present invention.

FIG. 5 illustrates a cross-sectional view of a gallium nitride (GaN)-based light-emitting diode (LED), in accordance with an embodiment of the present invention.

FIG. 6 illustrates a block diagram of an exemplary computer system, in accordance with an embodiment of the present invention.

FIG. 7 is a schematic cross-sectional view of an MOCVD chamber, in accordance with an embodiment of the present invention

FIG. 8 is a schematic view of an HVPE apparatus, in accordance with an embodiment of the present invention.

### DETAILED DESCRIPTION

Group III-nitride N-type doping techniques are described. In the following description, numerous specific details are set forth, such as fabrication conditions and material regimes, in order to provide a thorough understanding of embodiments of the present invention. It will be apparent to one skilled in the art that embodiments of the present invention may be practiced without these specific details. In other instances, well-known features, such as facility layouts or specific device layer stacks, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Disclosed herein are group III-nitride N-type doping techniques. In one embodiment, a hydride vapor phase epitaxy (HVPE) approach to group III-nitride N-type doping includes the use of SiH₄/Si₂H₆ and an additional chlorine source.

In conventional processes, a delivery line for chemical reaction chambers may rise to a temperature above suitability for a clean delivery. For example, conventional delivery processes may decompose SiH₄ (silane) and/or Si₂H₆ (disilane) to at least a certain extent in the delivery line, before arriving at the desired chemical reaction chamber. The addition of the more thermally robust disilane in greater ratio to silane has not improved the situation in many circumstances. In accordance with an embodiment of the present invention, chlorine is delivered in a delivery line along with SiH₄ and/or Si₂H₆. In one embodiment, the SiH₄ and/or Si₂H₆ is converted to a chloride species, e.g., SiHₓCl_{y} wherein the combination of x plus y is less than or equal to 4, among which SiCl₄ is the most thermodynamically stable.

Embodiments of the present invention may embrace, but is not limited to, one or more of the following concepts: (a) hydride vapor phase epitaxy (HVPE), (b) gallium nitride (GaN) and Group III-Nitrides, (c) doping, (d) light-emitting diodes (LEDs), (e) laser diodes (LDs), or (f) power devices.

Delivery of SiH₄ or Si₂H₆ in a reaction chamber during GaN deposition by metal-organic chemical vapor deposition (MOCVD) or HVPE may be a common technique for N-type doping of Group III-Nitride materials, and for GaN in particular. However, in the case of a hot wall HVPE reactor, silicon doping may be a challenge. Some of the challenging factors may be, but are not limited to, the design of the HVPE chamber being used. For example, different delivery lines may be used. Exemplary lines may be an ammonia (NH₃) delivery line, a GaCl₃ or GaCl (x=1, 2) delivery line, and even separate doping delivery line(s). The wall temperature of delivery lines (e.g., the temperature the delivered gas sees before even entering the reaction chamber) themselves may cover a wide range of temperatures (even up to GaN deposition temperature conditions).

In accordance with an embodiment of the present invention, use of an ammonia line for silicon (Si) doping based on SiH₄ or Si₂H₆ is not preferable due to the undesirable possibility of reaction between both precursors and ammonia leading to unwanted silicon nitride (e.g., Si₃N₄) deposition on the internal walls of the delivery line. Also, in one embodiment, using a GaCl₃ or GaCl (x=1, 2) delivery line or separate SiH₄/Si₂H₆ doping delivery line may have its own challenges. For example, high temperatures for the delivery lines in general (e.g., the most typical and desirable case for a hot wall HVPE reactor) and high residence time of gases in the delivery lines may lead to SiH₄ (or even Si₂H₆) decomposition. As a result, it may not be possible to reach desirable doping levels for GaN under such “competing” conditions for the deposition process.

In accordance with at least some embodiments of the present invention, the use of added chlorine (or HCl) flow in a delivery line prevents undesirable SiH₄ (or Si₂H₆) decomposition. In one embodiment, using added Cl₂ (or HCl), SiH₄ (or Si₂H₆) is converted into silicon chloride species in the delivery line. In a specific embodiment, the silicon chloride species are more stable gaseous compound(s) and reach a reaction chamber, such as an HVPE reaction chamber, without decomposition on hot walls of the delivery line.

In view of the above discoveries, and in accordance with at least some embodiments of the present invention, additional chlorine (or hydrogen chloride) flow is used to enhance Si doping by HVPE using both silane (SiH₄) and disilane (Si₂H₆) precursors. In one embodiment, a thick homogeneous Si-doped GaN (or a Group III-Nitride, in general) film is deposited using this approach. This approach may enable the continued, yet much improved, use of both SiH₄ and Si₂H₆ as precursors for N-type doping of Group III-Nitride materials, and GaN in particular by HVPE growth technique or any CVD growth technique with high temperature of the doping delivery line, such as may be the case for MOCVD.

Regarding embodiments involving doping in an HVPE process or chamber, one or more of the following factors may play a role: (a) in one embodiment, SiH₄ and/or Si₂H₆ are delivered using a GaCl₃ or GaCl (x=1, 2) delivery line or a separate SiH₄/Si₂H₆ doping delivery line, (b) in one embodiment, contact of both precursors (SiH₄ and Si₂H₆) and ammonia (NH₃) is avoided in the delivery line to prevent silicon nitride (e.g., Si₃N₄) formation, (c) in one embodiment, additional chlorine (or hydrogen chloride) added to the GaCl₃ or GaCl (x=1, 2), or a separate SiH₄/Si₂H₆ delivery line along with SiH₄ and/or Si₂H₆ enhances silicon (Si) incorporation in a group III-nitride film, e.g., as a result, in a specific embodiment, higher Si doping levels in GaN can be achieved at the same Si concentration in the gas phase of the chemical reaction chamber; and in a particular embodiment, doping levels at the level middle of the 10¹⁹ atoms cm⁻³ range can be achieved, (d) in one embodiment, low growth pressure (e.g., in the range of 100-250 Torr) during N-type GaN growth improves film morphology.

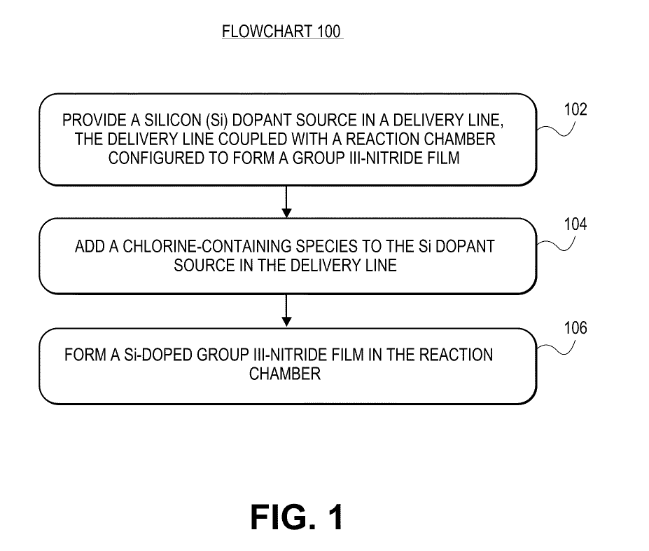

In an aspect of the present invention, approaches of N-type doping group III-V materials are provided. FIG. 1 is a Flowchart 100 representing operations in a method of fabricating an N-type doped group III-V material, in accordance with an embodiment of the present invention.

Referring to operation 102 of Flowchart 100, a method for N-type doping a group III-nitride film includes providing a silicon (Si) dopant source in a delivery line. The delivery line is coupled with a reaction chamber configured to form the group III-nitride film. Referring to operation 104, a chlorine-containing species is added to the Si dopant source in the delivery line. Referring to operation 106, using the Si dopant source, a Si-doped group III-nitride film is formed in the reaction chamber.

Conventionally, high Si doping levels may cause roughening of conventional thin GaN films grown on planar sapphire substrates. In the case of GaN deposition on a patterned sapphire substrate (PSS), high level silicon doping may result in significant GaN surface morphology degradation due to the PSS-based process being more sensitive and requiring additional effort for GaN surface morphology improvement. In accordance with an embodiment of the present invention, using added chlorine (Cl₂), or even hydrogen chloride (HCl), during n-type GaN deposition can significantly improve surface morphology for growth on both planar sapphire and PSS.

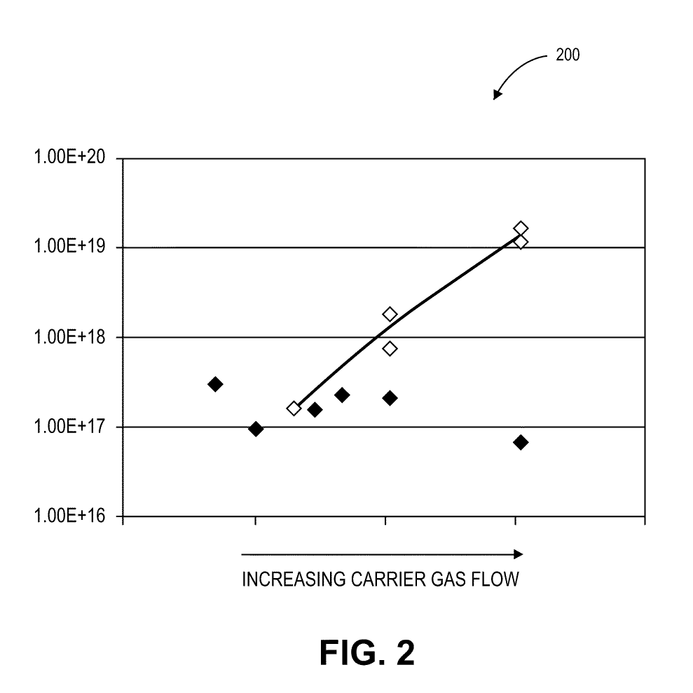

For example, applying techniques disclosed herein to GaN formation, desirable silicon (Si) doping levels in the GaN film may be achieved. For example, FIG. 2 is a plot 200 representing carrier concentration in n-type GaN (atoms/cm³) as a function of increasing nitrogen (N₂) flow, in accordance with an embodiment of the present invention. Referring to FIG. 2, included in the N₂ flows is 100 parts per million (ppm) of Si₂H₆ flow (a) without additional Cl₂ (black diamonds) and (b) with additional Cl₂ (grey diamonds) added. In an embodiment, a silicon doping level at the middle of the 10¹⁹ range can be achieved.

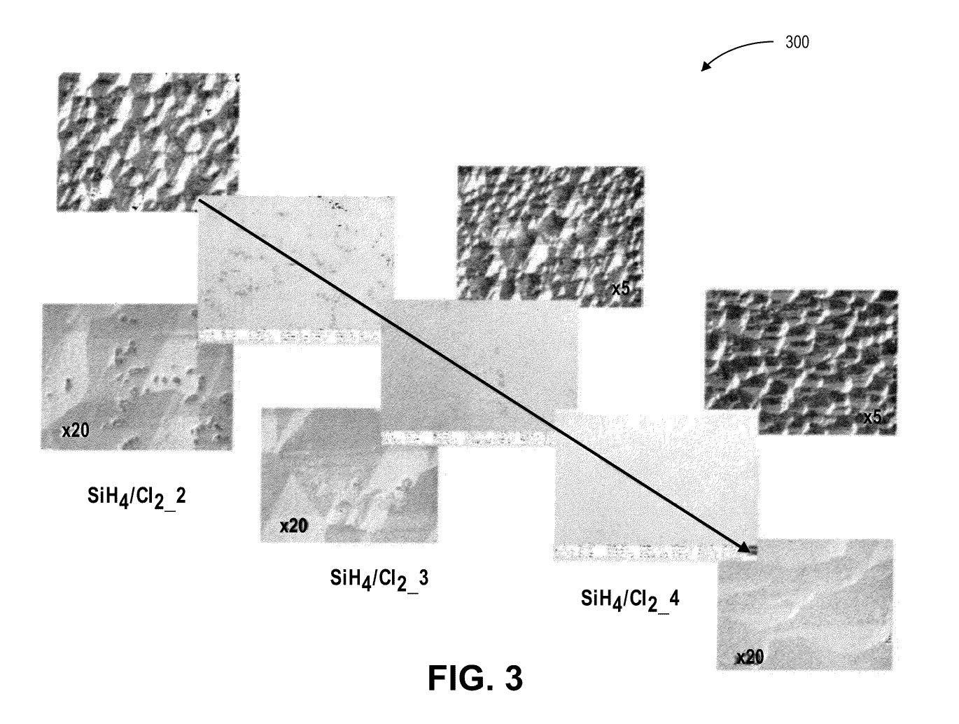

FIG. 3 includes representative optical microscope (OM) and scanning electron microscope (SEM) images 300 of GaN film grown on PSS at different added chlorine flow rates, in accordance with an embodiment of the present invention. Referring to FIG. 3, significant improvement of surface morphology is observed when added chlorine flow is used. Furthermore, when the process is performed at lower growth pressure (e.g., in the range of 100-250 Torr, versus say 450 Torr) morphology of grown films can be improved even further and thickness uniformity may also improve. In one embodiment, using one or more of the approaches described herein, doping level for carrier concentration exceeding 10¹⁸ cm⁻³ was achieved and a very smooth surface was obtained for the grown film, e.g., a GaN film. In a specific embodiment, layers having a thickness of up to 20 microns of Si-doped n-GaN can be fabricated. In a particular embodiment, a ratio of approximately 2:1 chlorine source gas flow to silicon dopant source gas flow is used. In another particular embodiment, a ratio of approximately 3:1 chlorine source gas flow to silicon dopant source gas flow is used. In another particular embodiment, a ratio of approximately 4:1 chlorine source gas flow to silicon dopant source gas flow is used.

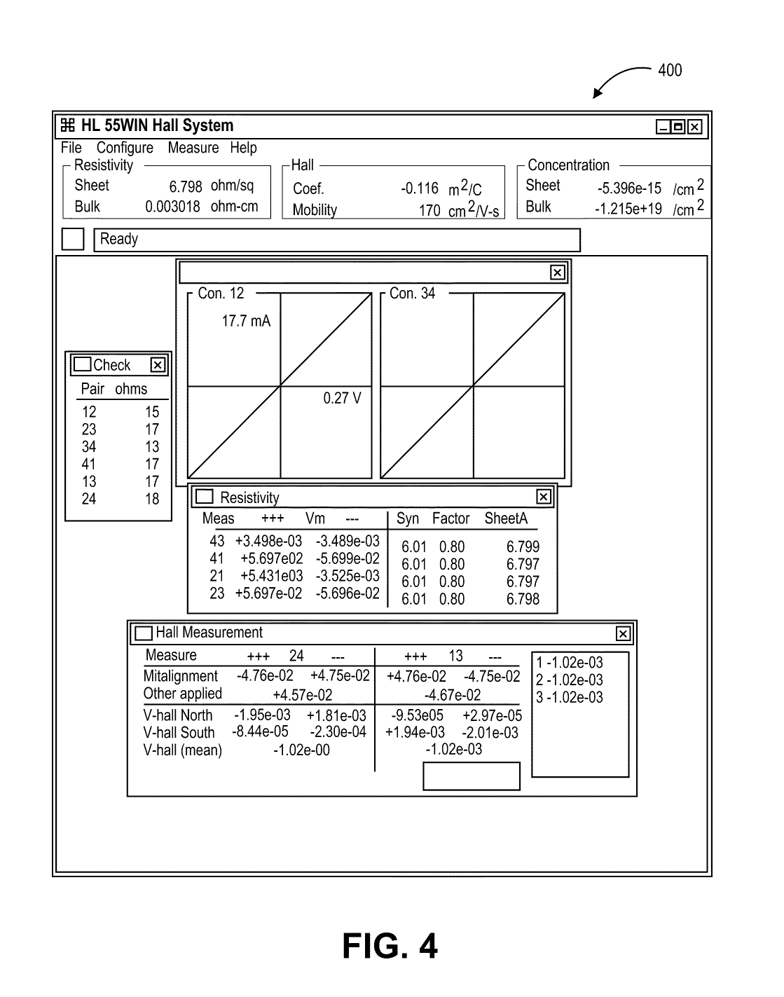

FIG. 4 illustrates a screen shot 400 of representative Hall measurements of thick n-type GaN films, in accordance with an embodiment of the present invention. Referring to FIG. 4, representative Hall measurements are provided showing high mobility 170 cm²/Vs at 1.2×10¹⁹ cm⁻³ carrier concentration for a GaN film.

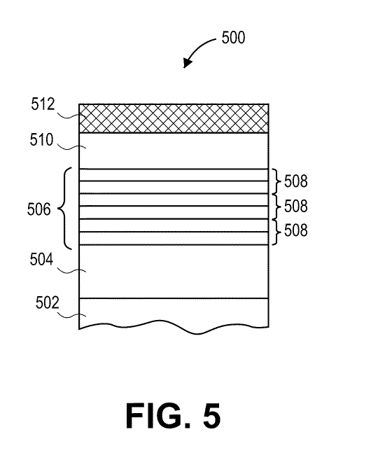

A group III-nitride layer fabricated by group III-nitride N-type doping techniques may be used in the fabrication of a light-emitting diode device. For example, FIG. 5 illustrates a cross-sectional view of a gallium nitride (GaN)-based light-emitting diode (LED), in accordance with an embodiment of the present invention.

Referring to FIG. 5, a GaN-based LED 500 includes an n-type GaN template 504 (e.g., n-type GaN, n-type InGaN, n-type AlGaN, n-type InAlGaN) on a substrate 502 (e.g., planar sapphire substrate, patterned sapphire substrate (PSS), silicon substrate, silicon carbide substrate). The GaN-based LED 500 also includes a multiple quantum well (MQW), or active region, structure or film stack 506 on or above the n-type GaN template 504 (e.g., an MQW composed of one or a plurality of field pairs of InGaN well/GaN barrier material layers 508, as depicted in FIG. 5). The GaN-based LED 500 also includes a p-type GaN (p-GaN) layer or film stack 510 on or above the MQW 506, and a metal contact or ITO layer 512 on the p-GaN layer.

LEDs and related devices may be fabricated from layers of, e.g., group III-V films, especially group III-nitride films. Some embodiments of the present invention relate to forming gallium nitride (GaN) layers in a dedicated chamber of a fabrication tool, such as in a dedicated MOCVD chamber. In some embodiments of the present invention, GaN is a binary GaN film, but in other embodiments, GaN is a ternary film (e.g., InGaN, AlGaN) or is a quaternary film (e.g., InAlGaN). In at least some embodiments, the group III-nitride material layers are formed epitaxially. They may be formed directly on a substrate or on a buffers layer disposed on a substrate. In some embodiments, there may not be a need for a p-type material on top of a structure of layers. Instead, an n-type or un-doped material may be used in place of the p-type layer.

It is to be understood that the utility of the above approaches is not limited to light-emitting diode technology. Other fields of use include, but are not limited to laser diodes or electronic devices such as field emission transistors or power devices.

Accordingly, disclosed herein are group III-nitride N-type doping techniques. For example, a group III nitride film is generally formed on or above a substrate. However, it is to be understood that embodiments of the present invention are not limited to formation of layers on patterned sapphire substrates. Other embodiments may include the use of any suitable patterned single crystalline substrate upon which an N-doped Group III-Nitride epitaxial film may be formed. The patterned substrate may be formed from a substrate, such as but not limited to a sapphire (Al₂O₃) substrate, a silicon (Si) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, a gallium nitride (GaN) substrate, an aluminum nitride (AlN) substrate, a gallium arsenide (GaAs) substrate, a spinel (MgAl₂O₄) substrate, a lithium gallium oxide (LiGaO₂) substrate, or a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices.

It is also to be understood that embodiments of the present invention need not be limited to GaN as a group III-V layer formed on a patterned or structural substrate. For example, other embodiments may include any N-doped Group III-Nitride epitaxial film that can be suitably deposited by hydride vapor phase epitaxy or MOCVD, or the like, deposition. The Group III-Nitride film may be a binary, ternary, or quaternary compound semiconductor film formed from a group III element or elements selected from gallium, indium and aluminum and nitrogen. That is, the Group III-Nitride crystalline film can be any solid solution or alloy of one or more Group III element and nitrogen, such as but not limited to GaN, AlN, InN, AlGaN, InGaN, InAlN, and InGaAlN. In a specific embodiment, the Group III-Nitride film is a gallium nitride (GaN) film. The Group III-Nitride film can have a thickness between 2-500 microns and is typically formed between 2-15 microns. Thicknesses greater than 500 microns are possible because of, e.g., the high growth rate of HVPE. In an embodiment of the present invention, the Group III-Nitride film has a thickness of at least 3.0 microns to sufficiently suppress threading dislocations. Additionally, the Group III-Nitride film can be N-type doped by species other than silicon. The Group III-Nitride film can be n type doped using any n type dopant such as but not limited to Si (as described above), Ge, Sn, Pb, or any suitable Group IV, Group V, or Group VI element. The Group III-Nitride film can be n type doped to a conductivity level of between 1×10¹⁶ to 1×10²⁰ atoms/cm³.

It is to be understood that on the above processes may be performed in a dedicated chamber within a cluster tool, or other tool with more than one chamber, e.g. an in-line tool arranged to have a dedicated chamber for fabricating layers of an LED. It is also to be understood that embodiments of the present invention need not be limited to the fabrication of LEDs. For example, in another embodiment, devices other than LED devices may be fabricated by approaches described herein, such as but not limited to field-effect transistor (FET) devices.

Embodiments of the present invention may be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

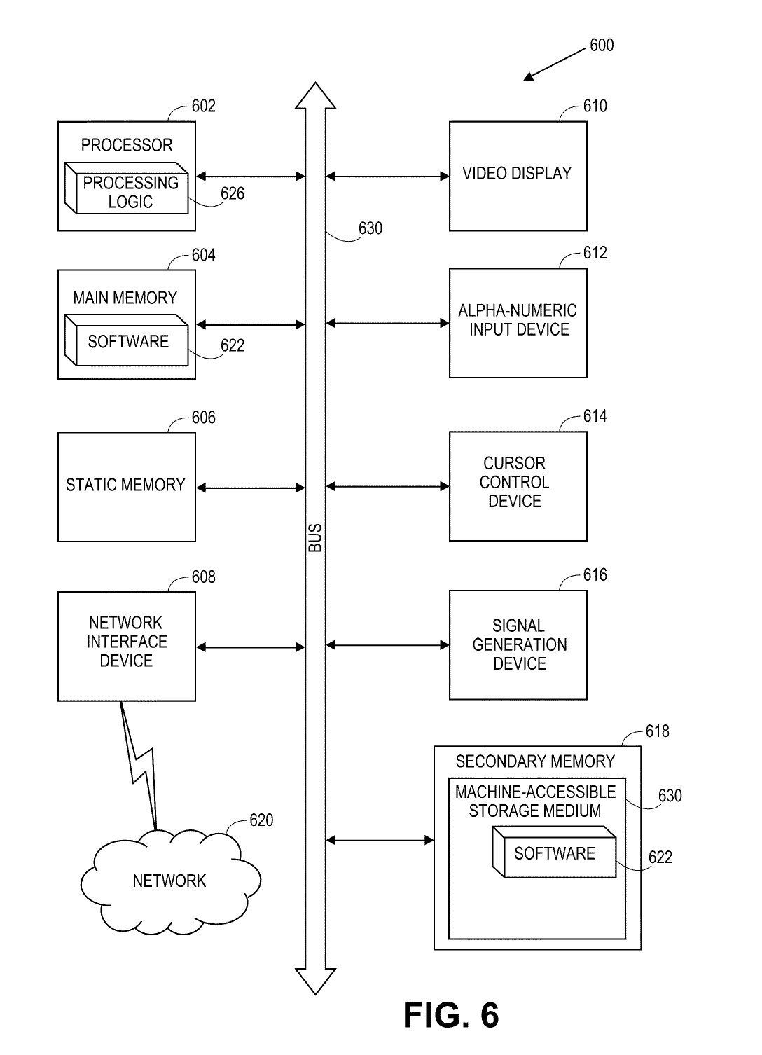

FIG. 6 illustrates a diagrammatic representation of a machine in the exemplary form of a computer system 600 within which a set of instructions, for causing the machine to perform any one or more of the processes discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the processes discussed herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the processes discussed herein.

The computer system 600 may further include a network interface device 608. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 1216 (e.g., a speaker).

The secondary memory 618 may include a machine-accessible storage medium (or more specifically a computer-readable storage medium) 631 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

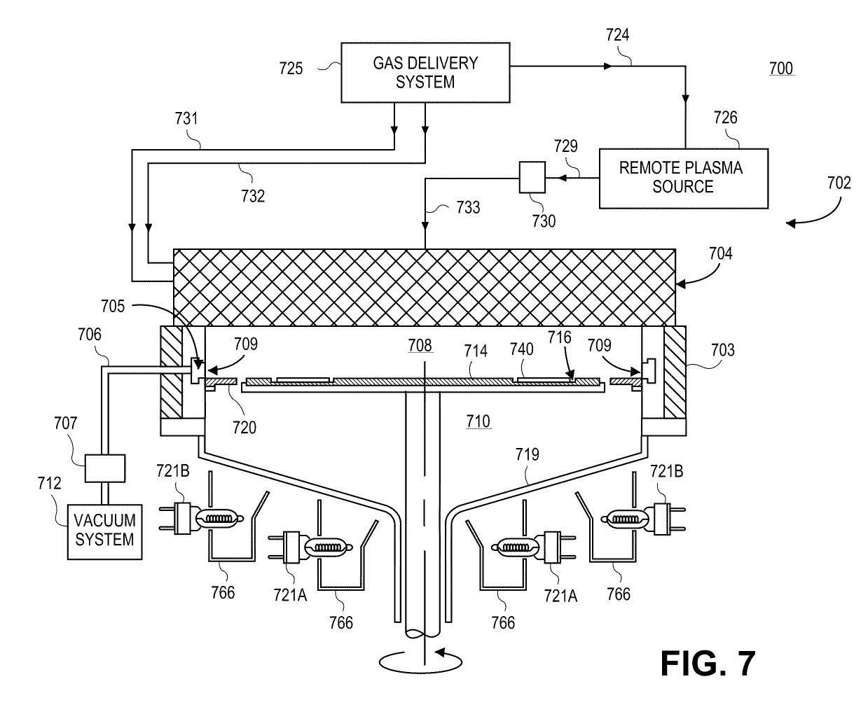

An example of an MOCVD deposition chamber which may be utilized for group III-nitride N-type doping techniques, in accordance with embodiments of the present invention, is illustrated and described with respect to FIG. 7. FIG. 7 is a schematic cross-sectional view of an MOCVD chamber according to an embodiment of the invention.

The apparatus 700 shown in FIG. 7 includes a chamber 702, a gas delivery system 725, a remote plasma source 726, and a vacuum system 712. The chamber 702 includes a chamber body 703 that encloses a processing volume 708. A showerhead assembly 704 is disposed at one end of the processing volume 708, and a substrate carrier 714 is disposed at the other end of the processing volume 708. A lower dome 719 is disposed at one end of a lower volume 710, and the substrate carrier 714 is disposed at the other end of the lower volume 710. The substrate carrier 714 is shown in process position, but may be moved to a lower position where, for example, the substrates 740 may be loaded or unloaded. An exhaust ring 720 may be disposed around the periphery of the substrate carrier 714 to help prevent deposition from occurring in the lower volume 710 and also help direct exhaust gases from the chamber 702 to exhaust ports 709. The lower dome 719 may be made of transparent material, such as high-purity quartz, to allow light to pass through for radiant heating of the substrates 740. The radiant heating may be provided by a plurality of inner lamps 721A and outer lamps 721B disposed below the lower dome 719, and reflectors 766 may be used to help control chamber 702 exposure to the radiant energy provided by inner and outer lamps 721A, 721B. Additional rings of lamps may also be used for finer temperature control of the substrate 740.

The substrate carrier 714 may include one or more recesses 716 within which one or more substrates 740 may be disposed during processing. The substrate carrier 714 may carry six or more substrates 740. In one embodiment, the substrate carrier 714 carries eight substrates 740. It is to be understood that more or less substrates 740 may be carried on the substrate carrier 714. Typical substrates 740 may include sapphire, silicon carbide (SiC), silicon, or gallium nitride (GaN). It is to be understood that other types of substrates 740, such as glass substrates 740, may be processed. Substrate 740 size may range from 50 mm-100 mm in diameter or larger. The substrate carrier 714 size may range from 200 mm-750 mm. The substrate carrier 714 may be formed from a variety of materials, including SiC or SiC-coated graphite. It is to be understood that substrates 740 of other sizes may be processed within the chamber 702 and according to the processes described herein. The showerhead assembly 704 may allow for more uniform deposition across a greater number of substrates 740 and/or larger substrates 740 than in traditional MOCVD chambers, thereby increasing throughput and reducing processing cost per substrate 740.

The substrate carrier 714 may rotate about an axis during processing. In one embodiment, the substrate carrier 714 may be rotated at about 2 RPM to about 100 RPM. In another embodiment, the substrate carrier 714 may be rotated at about 30 RPM. Rotating the substrate carrier 714 aids in providing uniform heating of the substrates 740 and uniform exposure of the processing gases to each substrate 740.

The plurality of inner and outer lamps 721A, 721B may be arranged in concentric circles or zones (not shown), and each lamp zone may be separately powered. In one embodiment, one or more temperature sensors, such as pyrometers (not shown), may be disposed within the showerhead assembly 704 to measure substrate 740 and substrate carrier 714 temperatures, and the temperature data may be sent to a controller (not shown) which can adjust power to separate lamp zones to maintain a predetermined temperature profile across the substrate carrier 714. In another embodiment, the power to separate lamp zones may be adjusted to compensate for precursor flow or precursor concentration non-uniformity. For example, if the precursor concentration is lower in a substrate carrier 714 region near an outer lamp zone, the power to the outer lamp zone may be adjusted to help compensate for the precursor depletion in this region.

The inner and outer lamps 721A, 721B may heat the substrates 740 to a temperature of about 400 degrees Celsius to about 1200 degrees Celsius. It is to be understood that the invention is not restricted to the use of arrays of inner and outer lamps 721A, 721B. Any suitable heating source may be utilized to ensure that the proper temperature is adequately applied to the chamber 702 and substrates 740 therein. For example, in another embodiment, the heating source may include resistive heating elements (not shown) which are in thermal contact with the substrate carrier 714.

A gas delivery system 725 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 702. Different gases, such as precursor gases, carrier gases, purge gases, cleaning/etching gases or others may be supplied from the gas delivery system 725 to separate supply lines 731, 732, and 733 to the showerhead assembly 704. The supply lines 731, 732, and 733 may include shut-off valves and mass flow controllers or other types of controllers to monitor and regulate or shut off the flow of gas in each line.

A conduit 729 may receive cleaning/etching gases from a remote plasma source 726. The remote plasma source 726 may receive gases from the gas delivery system 725 via supply line 724, and a valve 730 may be disposed between the showerhead assembly 704 and remote plasma source 726. The valve 730 may be opened to allow a cleaning and/or etching gas or plasma to flow into the showerhead assembly 704 via supply line 733 which may be adapted to function as a conduit for a plasma. In another embodiment, apparatus 700 may not include remote plasma source 726 and cleaning/etching gases may be delivered from gas delivery system 725 for non-plasma cleaning and/or etching using alternate supply line configurations to shower head assembly 704.

The remote plasma source 726 may be a radio frequency or microwave plasma source adapted for chamber 702 cleaning and/or substrate 740 etching. Cleaning and/or etching gas may be supplied to the remote plasma source 726 via supply line 724 to produce plasma species which may be sent via conduit 729 and supply line 733 for dispersion through showerhead assembly 704 into chamber 702. Gases for a cleaning application may include fluorine, chlorine or other reactive elements.

In another embodiment, the gas delivery system 725 and remote plasma source 726 may be suitably adapted so that precursor gases may be supplied to the remote plasma source 726 to produce plasma species which may be sent through showerhead assembly 704 to deposit CVD layers, such as films, for example, on substrates 740.

A purge gas (e.g., nitrogen) may be delivered into the chamber 702 from the showerhead assembly 704 and/or from inlet ports or tubes (not shown) disposed below the substrate carrier 714 and near the bottom of the chamber body 703. The purge gas enters the lower volume 710 of the chamber 702 and flows upwards past the substrate carrier 714 and exhaust ring 720 and into multiple exhaust ports 709 which are disposed around an annular exhaust channel 705. An exhaust conduit 706 connects the annular exhaust channel 705 to a vacuum system 712 which includes a vacuum pump (not shown). The chamber 702 pressure may be controlled using a valve system 707 which controls the rate at which the exhaust gases are drawn from the annular exhaust channel 705.

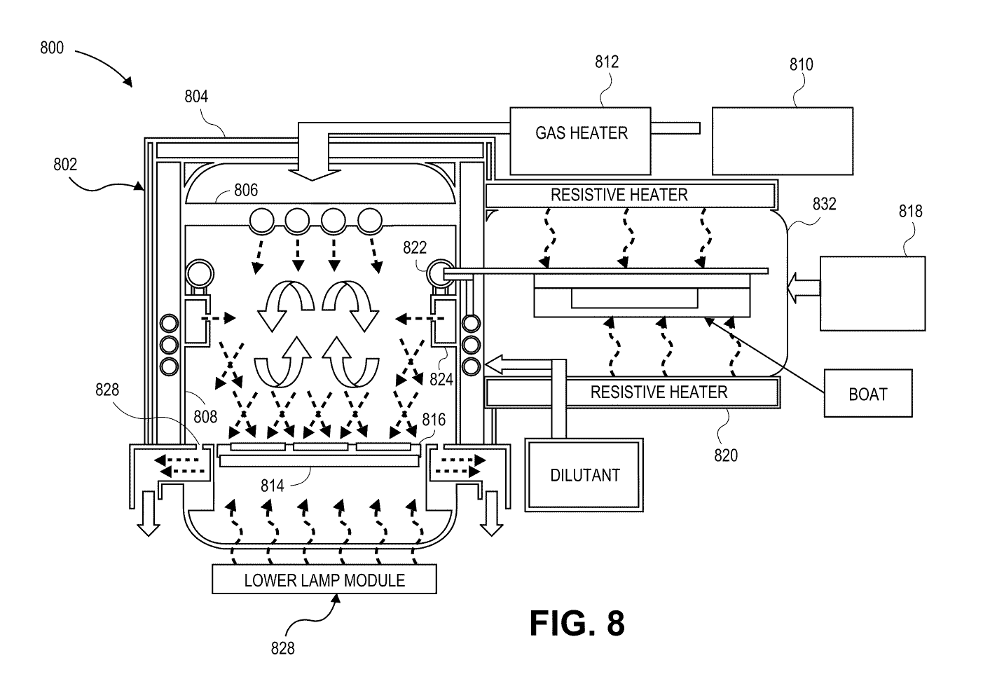

An example of a HVPE deposition chamber which may be utilized for group III-nitride N-type doping techniques, in accordance with embodiments of the present invention, is illustrated and described with respect to FIG. 8. FIG. 8 is a schematic view of an HVPE apparatus 800 according to one embodiment.

The apparatus 800 includes a chamber 802 enclosed by a lid 804. Processing gas from a first gas source 810 is delivered to the chamber 802 through a gas distribution showerhead 806. In one embodiment, the gas source 810 includes a nitrogen containing compound. In another embodiment, the gas source 810 includes ammonia. In one embodiment, an inert gas such as helium or diatomic nitrogen is introduced as well either through the gas distribution showerhead 806 or through the walls 808 of the chamber 802. An energy source 812 may be disposed between the gas source 810 and the gas distribution showerhead 806. In one embodiment, the energy source 812 includes a heater. The energy source 812 may break up the gas from the gas source 810, such as ammonia, so that the nitrogen from the nitrogen containing gas is more reactive.

To react with the gas from the first source 810, precursor material may be delivered from one or more second sources 818. The precursor may be delivered to the chamber 802 by flowing a reactive gas over and/or through the precursor in the precursor source 818. In one embodiment, the reactive gas includes a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 832 and be heated with the resistive heater 820. By increasing the residence time that the chlorine containing gas is snaked through the chamber 832, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactivity of the precursor, the precursor may be heated by a resistive heater 820 within the second chamber 832 in a boat. The chloride reaction product may then be delivered to the chamber 802. The reactive chloride product first enters a tube 822 where it evenly distributes within the tube 822. The tube 822 is connected to another tube 824. The chloride reaction product enters the second tube 824 after it has been evenly distributed within the first tube 822. The chloride reaction product then enters into the chamber 802 where it mixes with the nitrogen containing gas to form a nitride layer on a substrate 816 that is disposed on a susceptor 814. In one embodiment, the susceptor 814 includes silicon carbide. The nitride layer may include n-type gallium nitride for example. The other reaction products, such as nitrogen and chlorine, are exhausted through an exhaust 826.

It is to be understood that reaction conditions, such as pressure, may vary by application and desired outcome. However, in accordance with an embodiment of the present invention, during the deposition process the chamber is an HVPE chamber and the chamber pressure is maintained approximately in the range of 70 Torr to 550 Torr. In another embodiment, chamber pressure is maintained approximately in the range of several Torr to atmospheric pressure.

Thus, group III-nitride N-type doping techniques are described.

What is claimed is:

1. A method for N-type doping a group III-nitride film comprising:
providing a silicon (Si) dopant source in a delivery line, the delivery line coupled with a reaction chamber configured to form the group III-nitride film;
adding a chlorine-containing species to the Si dopant source in the delivery line; and
forming, using the Si dopant source, a Si-doped group III-nitride film in the reaction chamber.

2. The method of claim 1, wherein the chlorine-containing species comprises gaseous chlorine (Cl₂).

3. The method of claim 1, wherein the chlorine-containing species comprises gaseous hydrogen chloride (HC).

4. The method of claim 1, wherein the silicon (Si) dopant source is SiH₄.

5. The method of claim 1, wherein the silicon (Si) dopant source is Si₂H₆.

6. The method of claim 1, wherein the silicon (Si) dopant source is a combination of Si₂H₆ and SiH₄.

7. A system, comprising:
a reaction chamber configured to form a group III-nitride film; and
a delivery line coupled with the reaction chamber, wherein the system is configured to perform a method for silicon (Si) doping a group III-nitride film, the method comprising:
providing a Si dopant source in the delivery line;
adding a chlorine-containing species to the Si dopant source in the delivery line; and
forming, using the Si dopant source, a Si-doped group III-nitride film in the reaction chamber.

8. The system of claim 7, wherein the chlorine-containing species comprises gaseous chlorine (Cl₂).

9. The system of claim 7, wherein the chlorine-containing species comprises gaseous hydrogen chloride (HCl).

10. The system of claim 7, wherein the silicon (Si) dopant source is SiH₄.

11. The system of claim 7, wherein the silicon (Si) dopant source is Si₂H₆.

12. The system of claim 7, wherein the silicon (Si) dopant source is a combination of Si₂H₆ and SiH₄.

13. The system of claim 7, wherein the delivery line to the reaction chamber is a group III source delivery line.

14. The system of claim 7, wherein the delivery line to the reaction chamber is a separate silicon (Si) dopant delivery line.

15. The system of claim 13, wherein the group III source delivery line is a gallium source delivery line.

16. The system of claim 13, wherein the group III source delivery line is an aluminum source delivery line.

17. The system of claim 13, wherein the group III source delivery line is an indium source delivery line.

18. The system of claim 13, wherein the group III source delivery line is a delivery line for sources of any combination of Ga, Al, and/or In, such as Ga and Al and In, Ga and Al, Ga and In, Al and In.

19. The system of claim 7, wherein the reaction chamber is a HVPE reaction chamber.

20. The system of claim 7, wherein the reaction chamber is a MOCVD reaction chamber.
